(19) United States
(12) Patent Application Publication
(10) Pub. No.: US 2004/0031518 A1
(43) Pub. Date: Feb. 19, 2004

(54) Roofing element comprising at least one solar cell

(76) Inventor: Wilco Johan Thomas Plantfeber, Nijmegen (NL)

Correspondence Address: WEBB ZIESENHEIM LOGSDON ORKIN & HANSON, P.C., 700 KOPPERS BUILDING, 436 SEVENTH AVENUE, PITTSBURGH, PA, 15219, US

(21) Appl. No.: 10/389,583

(22) Filed: Mar. 14, 2003

Related U.S. Application Data
(63) Continuation of application No. 09/719,733, filed on Feb. 13, 2001, now abandoned.
Application No. 09/719,733 is a 371 of international application No. PCT/NL99/00375, filed on Jun. 16, 1999.

(30) Foreign Application Priority Data
Jun. 16, 1998 (NL) NL 1009418

(51) Int. Cl. H01L 25/00

(52) U.S. Cl. 136/251; 136/244; 52/173.3

(57) ABSTRACT

The invention relates to a roofing element (1) comprising at least one electric solar cell. The roofing element has the shape of a plurality of roofing tiles (2) overlappingly arranged relative to each other in rows and/or columns. The at least one solar cell (4) can have the shape of a plurality of roofing tiles overlappingly arranged relative to each other in rows/or columns.

This invention relates to a roofing element comprising at least one electric solar cell.

Such a roofing element is known, for instance, from DE-U1-295 10 147. This document discloses a roofing element in the form of, and having the dimensions of, a regular roofing tile, which is provided with a solar cell. With these roofing tile elements, known per se, a roof covering can be assembled which is also adapted for generating electric energy. A disadvantage of the known roofing element is that a great multiplicity of roofing elements are needed for assembling a roof covering, which roofing elements moreover need to be electrically connected with each other for delivering the electric energy generated in the solar cells of these elements. This renders the whole susceptible to trouble. Moreover, in a roof covering composed of such roofing elements, a large number of electrical interconnections are necessary, which is a relatively costly affair.

The object or the invention is to meet the disadvantages outlined above. Accordingly, the roofing element according to the invention is characterized in that the roofing element has the shape of a plurality of roofing tiles overlappingly arranged relative to each other in rows and/or columns.

Because the roofing element has the shape (and hence the dimensions) of a plurality of roofing tiles which are overlappingly arranged relative to each other in rows and/or columns, the advantage is gained that far fewer roofing elements are required to be assembled into a roof covering than in the known system outlined above. Preferably, the at least one electric solar cell has the form of a plurality of roofing tiles overlappingly arranged in rows and/or columns. As a result, the at least one solar cell will have a surface area much greater than in the known roofing elements, while a further achievement is that the appearance of the roofing element in its entirety retains the form of a plurality of roofing tiles overlappingly arranged relative to each other in rows and/or colmns.

A roof covering composed of a roofing element according to the invention is therefore undistinguishable from a roof covering made up of regular roofing tiles. Preferably, the roofing element is provided with a single electrical connection for connecting the at least one solar cell.

Because fewer roofing elements according to the invention are needed to be composed into a roof covering, fewer electrical connections are therefore needed than in the known system. Consequently, a roof covering comprising roofing elements according to the invention is less susceptible to failure and moreover relatively inexpensive.

In particular, the roofing element is made up of a rigid plate which has the shape of a plurality of roofing tiles overlappingly arranged relative to each other in rows and/or columns, and the at least one solar cell, while the at least one solar cell is provided on a side of the rigid plate which, in use, is at the upper side of the roofing element.

According to a preferred embodiment, however, the roofing element is made up of a rigid plate transparent to sunlight, which has the shape of a plurality of roofing tiles overlappingly arranged relative to each other in rows and/or columns, while the at least one solar cell is provided on a side of the rigid plate which, in use, is at the bottom side of the roofing element.

The advantage of this embodiment is that the at least one solar cell is protected by the transparent rigid plate frome external weather influences. This renders the roofing element particularly reliable, while moreover the life of the at least one solar cell is prolonged.

For the particular embodiments outlined above, it is preferred that the at least one solar cell is manufactured from a flexible sheetlike material. In particular, the at least one solar cell is glued into the rigid plate. However, other joints are also possible.

According to a particular embodiment of the roofing element according to the invention, only a portion of the rigid plate which, in use as a roof covering in combination with other roofing elements, is not covered by these other roofing elements, is provided with the at least one solar cell.

What is thus accomplished is that only those portions of the roofing element which in use are exposed to light, and hence can field electric energy, are possibly provided with the at least one solar cell.

In particular, the roofing element is further provided with electric terminal clamps for delivering electric energy generated by the at least one solar cell.

The roofing element can, for instance, have a standard size of 1.1 m×8.4 m. In general, the roofing element will have a surface area greater than 2 m². It is also possible, however, that the roofing element has such dimensions that only one roofing element is needed to form a roof covering.

According to a highly advanced embodiment, the roofing element further comprises at least one fluid flow channel for heating fluid through solar energy, which fluid, in use as a roof covering, flows through the channel.

In this way, both electric and thermal energy can be generated.

The invention will presently be further explained with reference to the drawings, wherein:

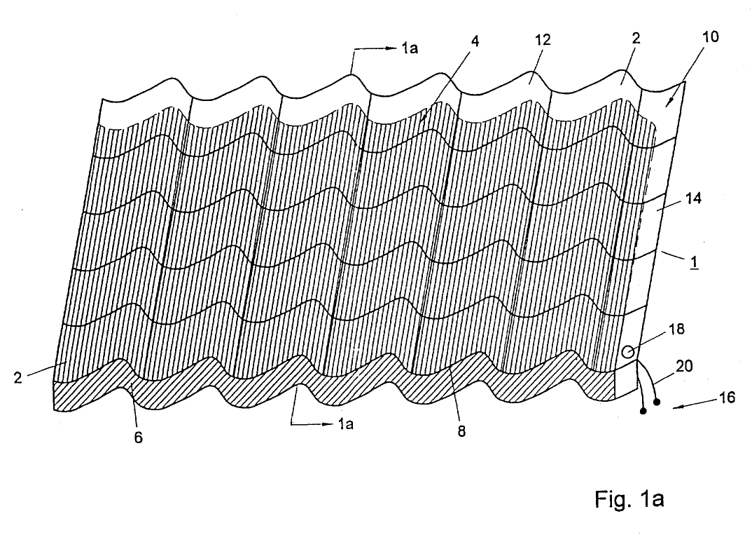

FIG. 1a shows a first embodiment of a roofing element according to the invention;

FIG. 1b shows a cross section of the roofing element according to FIG. 1a;

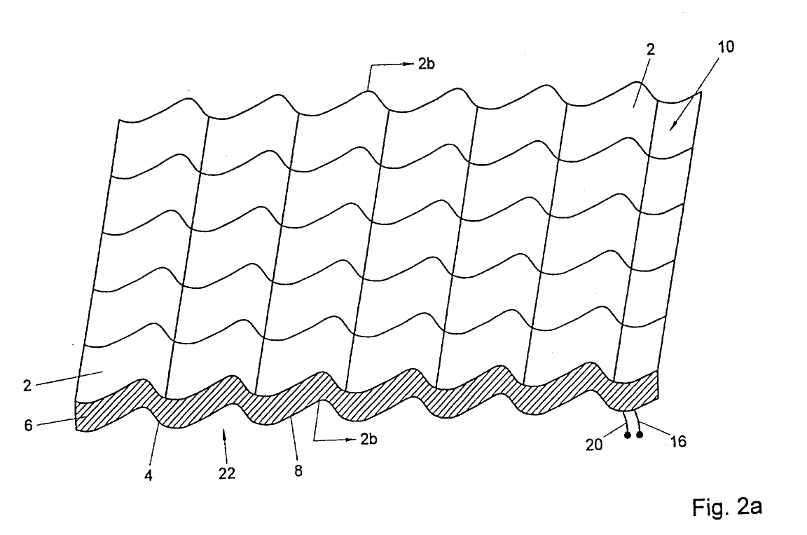

FIG. 2a shows a second embodiment of a roofing element according to the invention;

FIG. 2b shows a cross section of the roofing element according to FIG. 2a;

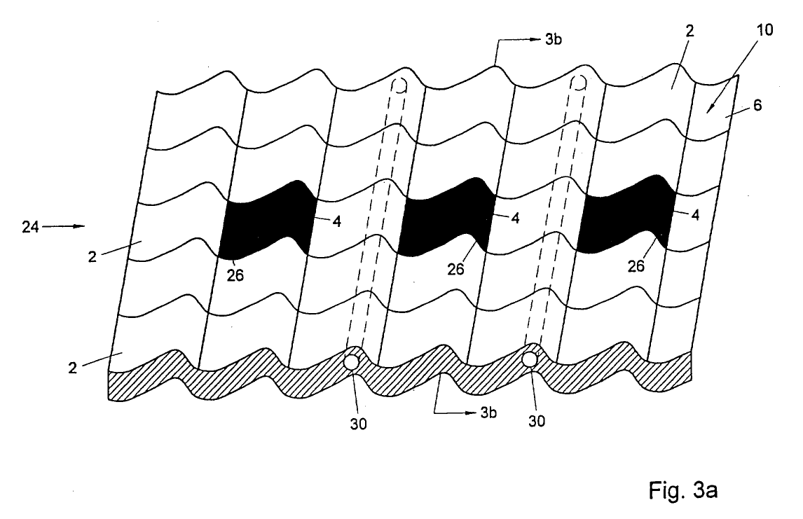

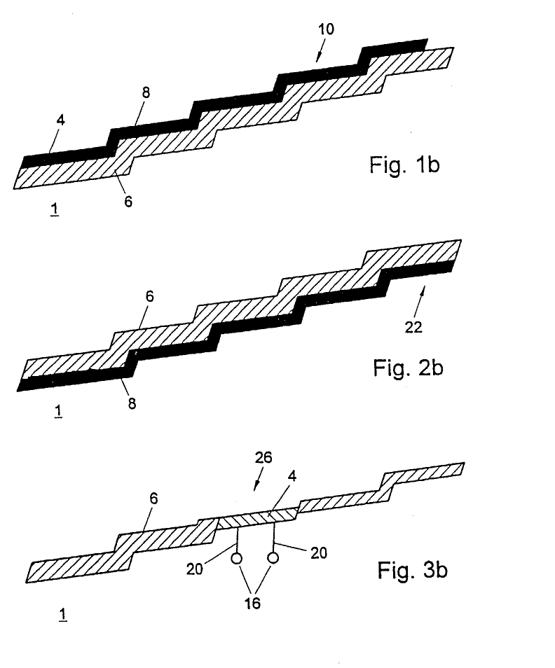

FIG. 3a shows a third embodiment of a roofing element according to the invention;

FIG. 3b shows a cross section of the roofing element according to FIG. 3a; and

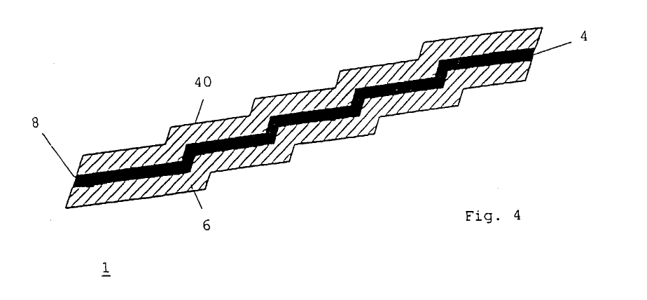

FIG. 4 shows a cross section of a fourth embodiment according to the invention.

Referring to FIGS. 1a and 1b, a first embodiment of a roofing element according to the invention will be described. In FIG. 1a, the roofing element is designated by reference numeral 1.

The roofing element 1 has the shape of a plurality of roofing tiles 2. In this example almost the entire roofing element has the shap of a plurality of roofing tiles overlappingly arranged relative to each other in rows and/or columns. In this example, the roofing element is in the form of five horizontal rows of roofing tiles, each comprising six roofing tiles. The roofing tiles are overlappingly arranged relative to each other in rows and columns.

The roofing element further comprises a solar cell 4, which likewise has the shape of a plurality of roofing tiles overlappingly arranged relative to each other in rows and columns. More particularly, the roofing element 1 is made up of a rigid plate 6, which has the shape of said plurality of roofing tiles overlappingly arranged relative to each other in rows and columns, and the at least one solar cell. The solar cell 4 is manufactured from a flexible sheetlike material 8, known per se. In this example, the at least one solar cell, i.e., the sheetlike material 8, is provided on a side 10 of the rigid plate 6 which, in use, is at the upper side of the roofing element. In other words, the solar cell 4 is at the upper side of the roofing element 1. In this example, the sheetlike material 8, known per se, comprises a plurality of solar cells. These solar cells are electrically connected in parallel and/or in series. In this example, the at least one solar cell 4, i.e., the sheetlike material 8, is glued onto the rigid plate 6. It is also conceivable, however, that other techniques are used to attach the at least one solar cell 4 to the rigid plate 6. The plate 6 can consist of a metal roofing tile plate known per se.

In use, a roof covering of a house and/or building can be formed by at least one roofing element. More particularly, a limited number of roofing elements will be used to be composed into a roof covering. The roofing elements are also stacked so as to overlap. As can be seen in FIG. 1a, only a portion of the rigid plate 6 that, in use as a roof covering in combination with other roofing elements, is not covered by these other roofing elements, is provided with the at least one solar cell (i.e., in this example, the sheetlike material 8). Accordingly, the horizontal edge 12 and the vertical edge 14 are not covered by the sheetlike material 8. These are the edges which, when the roofing element 1 in question is assembled together with other roofing elements to form the roof covering, lie under these other roofing elements.

The roofing element further comprises an electrical connection in the form of electrical terminal clamps 16 for delivering electric energy generated by the at least one solar cell 4, 8. To that end, in the roofing element a wire passage 18 is provided, through which electrical connecting wires 20, provided with the terminal clamps 16 at their free ends, have been passed from the side 10 of the roofing element to the side of the roofing element located opposite side 10. The passage 18 is provided at a position which, in use as a roof covering in combination with at least one other roofing element, is covered by this other roofing element. Leakage is thus prevented. What is moreover achieved is that the electrical connecting wires 20 are protected from external weather influences.

FIGS. 2a and 2b show a second embodiment of a roofing element according to the invention. Parts corresponding with FIGS. 1a and 1b are provided with the same reference numerals. In the second embodiment, the roofing element comprises a rigid plate 6 transparent to sunlight, which is made, for instance, of glass or a transparent plastic. The tranparent rigid plate 6 again has the shape of a plurality of roofing tiles 2 overlappingly arranged relative to each other in rows and/or columns. In this example, the at least one solar cell 4 is provided on a side 22 of the rigid plate 6 which, in use, is at the bottom side of the roofing element. In use, sunlight will be incident on the side 10 of the roofing element and subsequently reach the at least one solar cell 4 via the transparent plate 6. The at least one solar cell 4 in this example is again made of the sheetlike flexible material, known per se, which is attached to the rigid plate 6 using, for instance, transparent glue. Because in this example the at least one solar cell 4 is attached to the bottom side of the rigid plate, the passage 18 discussed in relation to FIGS. 1a and 1b can be omitted. However, the above-mentioned terminal clamps 16 and the connecting wires 20 are present.

Finally, referring to FIGS. 3a and 3b, a third embodiment of a roofing element according to the invention is discussed. Again, parts corresponding to the preceding figures are provided with the same reference numerals.

The roofing element again comprises a metal rigid plate 6 which has the shape of a plurality of roofing tiles which are arranged relative to each other in rows and/or columns. However, in the central row 24 of roofing tiles 2 arranged horizontally relative to each other, three openings 26 are provided, of a size of a single roofing tile 2. In each of these openings 26, a solar cell 4 is fitted. In contrast to the embodiments outlined hereinbefore, the solar cell 4 is not made of a sheetlike flexible material. Nor is this necessary, since the solar cell 4 can presently take a thickness greater than, equal to, or less than the thickness of the rigid plate 6. However, each solar cell 4 has the shape of a roofing tile. Accordingly, the solar cells 4 are likewise overlappingly arranged relative to each other in rows and/or columns. Each solar cell 4 is provided with electrical terminal clamps 16 and electrical connecting wires 20. The solar cells 4, before fitting the roofing tile plate on a roof, for instance in the factory, can be electrically interconnected, in a series or parallel connection or a combination thereof.

The roofing element 1 further comprises two fluid flow channels 30 each arranged for heating a fluid (liquid or gas) by means of solar energy, which fluid, in use, flows through each of the channels 30. In fact, the channels 30 are each provided in the metal rigid plate 6. Because the plate 6 will heat up under the influence of the sun, the fluid flowing through the channels 30 will also be properly heated. The roofing element according to FIG. 3a is therefore suitable for generating electric and thermal energy.

The invention is not limited in any way to the embodiments outlined hereinbefore. Thus, the [symbol] may also have the shape of only one row of roofing tiles 2 overlappingly arranged relative to each other. The roofing element may also have the shape of only one column of roofing tiles overlappingly arranged relative to each other. Preferably, however, the roofing element has the form of roofing tiles overlappingly arranged relative to each other in rows and columns. The roofing element will then preferably have a standard dimension (for instance length) of 1.1 m×8.4 m. The solar cell 4 and/or the rigid plate 6 can be of various colors. In particular, the at least one solar cell 4 can be of a color which corresponds to the color of a real roofing tile. In particular, in the first and third embodiments, the at least one solar cell is of a color corresponding to the color of the rigid plate 2. The solar cell can consist of translucent and non-translucent solar cells. In the roofing element, a converter may be arranged. The roofing element may have such a size that it can be cover a whole roof. The rigid plate may be made of various materials, such as plastic, polyester, glass, or recycled waste material. The rigid plate 6 may also consist of a commercially available roofing tile plate, known per se. In the case where the rigid plate is made of metal, it is preferably made of steel or aluminum. The roofing element may further be provided with an insulating material at its bottom side 22. A rigid plate can be fitted over an existing roof. The roofing element may also be provided with at least two planar electric solar cells so positioned relative to each other that these electric solar cells take the shape of at least a part of a roofing tile. Also, this electric solar cell may be of (rigid) curved design. It is also possible that during manufacture the electric solar cell 4 is applied to the plate 6 in layers. At least one or all layers may, for example, at least contain Si. It is also possible for at least one or all layers at least to contain copper indium diselenide (abbreviated to CIS). Also, various other ways of manufacture are possible. Further, it is possible to apply a layer over the roofing element which provides for an intensive and better distributed light incidence on the solar cell. When various roofing elements are used to assemble a roof covering, the solar cells of these roofing elements can be connected in parallel and/or in series. Naturally, one of the possibilities is to store the electric energy left in batteries and/or to return it to the electricity grid. The electric solar cell 4 can be located under, on, or in the rigid plate 6. As shown in FIG. 4, can on the solar cell 8, in the way that this has been fitted in the construction shap according to FIG. 1a and FIG. 1b, can be fitted with transparant covering material 40. This material may consist of, for example, rigid or soft plastic. Glass would also be a possibility. Solar cell 8 has in fact been included in the rigid plate in this case, the rigid plate has been provided by reference number 6 and 40 in FIG. 4. Likewise, the fluid flow channel 30 can be located under, on, or in the rigid plate 6. It is also possible to couple those fluid flow channels of the various roofing elements to each other. Further, it is also possible that the electric solar cell 4 is located under or above the fluid flow channel. Furthermore, in or under the rigid plate 6, an insulated collector can be mounted, eliminating the need for a separate storage vessel. This collector is then integrated into the rigid plate. Further, other methods of generating thermal energy are also possible. The roofing element can consist of prefabricated modular roof elements which can be joined together in a simple manner. An example of these modular roof elements, which, for instance, can be joined together on the roof, involves several regular roofing tiles and a flexible solar cell provided with a lock and hook system or an adhesive edge. Further, it is possible to collect rain water; this water can optionally be recycled.

Such variants and applications are all understood to fall within the scope of the invention. Loose modular roof elements which can subsequently be joined together to form the roofing element according to the invention are also understood to fall within the scope of the invention.

1. A roofing element comprising at least one electric solar cell, characterized in that the roofing element has the shape of a plurality of roofing tiles overlappingly arranged relative to each other in rows and/or columns.

2. A roofing element according to claim 1, characterized in that the at least one electric solar cell has the shape of a plurality of roofing tiles overlappingly arranged relative to each other in rows and/or columns.

3. A roofing element according to claim 1 or 2, characterized in that the roofing element is composed of a rigid plate and the at least one solar cell, while the at least one solar cell is provided on a side of the rigid plate which, in use, is at the upper side of the roofing tile plate.

4. A roofing element according to claim 3, characterized in that the at least one solar cell is of a color which corresponds to the color of the rigid plate.

5. A roofing element according to claim 3 or 4, characterized in that on at least one solar cell a transparent covering material has been fitted, this material has the shape of a plurality of roofing tiles overlappingly arranged relative to each other in rows and/or columns.

6. A roofing element according to claim 1 or 2, characterized in that the roofing element is composed of a rigid plate transparent to sunlight, which has the shape of a plurality of roofing tiles overlappingly arranged relative to each other in rows and/or columns, and the at least one solar cell, while the at least one solar cell is provided on a side of the rigit plate which, in use, is at the bottom side of the roofing tile plate.

7. A roofing element according to claim 3,4,5 or 6, characterized in that the at least one solar cell is manufactured from a flexible sheetlike material.

8. A roofing element according to any one of the preceding claims 3-7, characterized in that the roofing element comprises a plurality of solar cells.

9. A roofing element according to claim 8, characterized in that the solar cells are connected in parallel and/or in series.

10. A roofing element according to any one of the preceding claims 3-8, characterized in that the at least one solar cell is glued onto the rigid plate.

11. A roofing element according to any one of the preceding claims 3-10, characterized in that only a portion of the rigid plate that, in use as a roof covering in combination with other roofing elements, is not covered by these other roofing elements, is provided with the at least one solar cell.

12. A roofing element according to any one of the preceding claims, characterized in that the roofing element is further provided with electric terminal clamps for delivering electric energy generated by the at least one solar cell.

13. A roofing element according to any one of the preceding claims, characterized in that the roofing element has a surface area greater than 2 m².

14. A roofing element according to claim 13, characterized in that the roofing element has a size of 1.1 m×8.4 m.

15. A roofing element according to any one of the preceding claims, characterized in that the roofing element further comprises at least one fluid flow channel for heating a fluid by means of solar energy, which fluid, in use as a roof covering, flows through the channel.

16. A roofing element according to any one of the preceding claims, characterized in that in the roofing element a passage is provided for passing therethrough connecting wires for the at least one solar cell, the passage being provided at a position which, in use as a roof covering in combination with at least one other roofing element, is covered by this other roofing element.

17. A roofing element according to any one of the preceding claims, characterized in that the solar cell, during the manufacturing process, has been applied in layers directly to the roofing element.

18. A roofing element according to any one of the preceding claims, characterized in that at least one of these layers contains at least Si.

19. A roofing element according to any one of the preceding claims, characterized in that at least one of these layers contains at least copper indium diselenide.

20. A roofing element according to any one of the preceding claims, characterized in that the roofing element is composed of prefabricated modular roof elements which can be joined together in a simple manner.

21. A roofing element according to any one of the preceding claims, characterized in that the roofing element comprises one electrical connection for connecting the at least one solar cell.

22. A roof covering composed of a plurality of roofing elements according to any one of the preceding claims.

23. A roofing element according to claim 3, characterized in that the rigid plate has the shape of a plurality of roofing tiles overlappingly arranged relative to each other in rows and/or columns
